(19) United States
(12) Patent Application Publication
(10) Pub. No.: US 2014/0146452 A1
(43) Pub. Date: May 29, 2014

(54) ELECTRONIC DEVICE AND HOUSING

(71) Applicant: HON HAI PRECISION INDUSTRY CO., LTD., New Taipei (TW)

(72) Inventors: HUNG-YUN CHU, New Taipei (TW); CHANG-WEI TSAO, New Taipei (TW)

(73) Assignee: HON HAI PRECISION INDUSTRY CO., LTD., New Taipei (TW)

(21) Appl. No.: 14/091,354

(22) Filed: Nov. 27, 2013

(30) Foreign Application Priority Data
Nov. 29, 2012 (TW) 101144722

(51) Int. Cl. H05K 5/00; B32B 3/26; B32B 1/02

(52) U.S. Cl. CPC H05K 5/0008; B32B 1/02; B32B 3/266
USPC 361/679.01; 428/34.1

(57) ABSTRACT

A housing of electronic device includes a back shell defining an assembly hole, a main body, a fixing element comprising a head, and a connection element fixed to the back shell. The connection element defines a receiving hole for receiving the head of the fixing element and a through hole aligned with the assembly hole. The inner diameter of the assembly hole is smaller than an inner diameter of the receiving hole and the diameter of the head of the fixing element. The assembly hole may receive a shank of a screwdriver that threads the fixing element into the main body. An electronic device including the housing is also provided.

### BACKGROUND

1. Technical Field

The present disclosure relates to electronic devices and housings, and particularly to, an electronic device having a housing defining a hole for assembly.

2. Description of Related Art

Many electronic devices such as electronic readers, portable computers, and mobile phones for example, include a main body and a housing fixed to the main body by screws. The housing of an electronic device defines through holes for receiving heads of the screws. The diameter of each through hole is greater than the diameter of the head of the screw for receiving the head of the screw. Thus, the head of the screw is not exposed from the front surface of the housing. To further improve the look of the electronic device, rubber is filled in the through hole to shield the heads of the screws. However, the rubber may move out of the holes in certain circumstances, and the rubber shield on the head of the screw increases the difficulty of assembly and disassembly of the electronic device.

Therefore, what is needed is an electronic device and a housing thereof to alleviate the limitations described above.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding sections throughout the several views.

FIG. 1 is a partial, isometric view of a housing of an electronic device in accordance with an exemplary embodiment.

FIG. 2 is an exploded view of the housing of FIG. 1.

FIG. 3 is an isometric view showing a connection element assembled with the housing of FIG. 1.

FIG. 4 is a cross-section view of the housing of FIG. 1, taken along line V-V.

FIG. 5 is a schematic view of the assembly of the housing of FIG. 1.

FIG. 6 is an isometric view of a back shell of the housing of FIG. 1.

### DETAILED DESCRIPTION

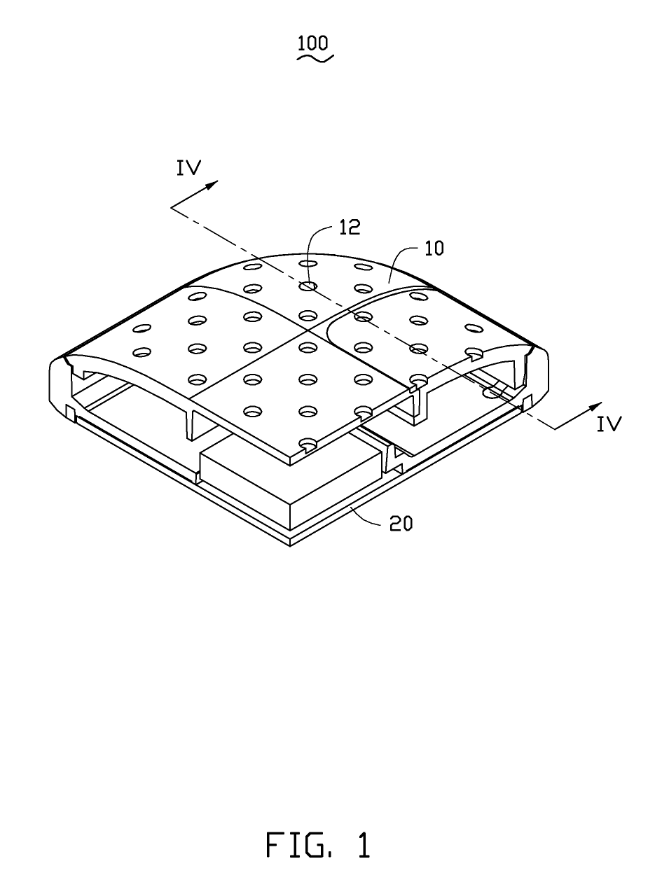

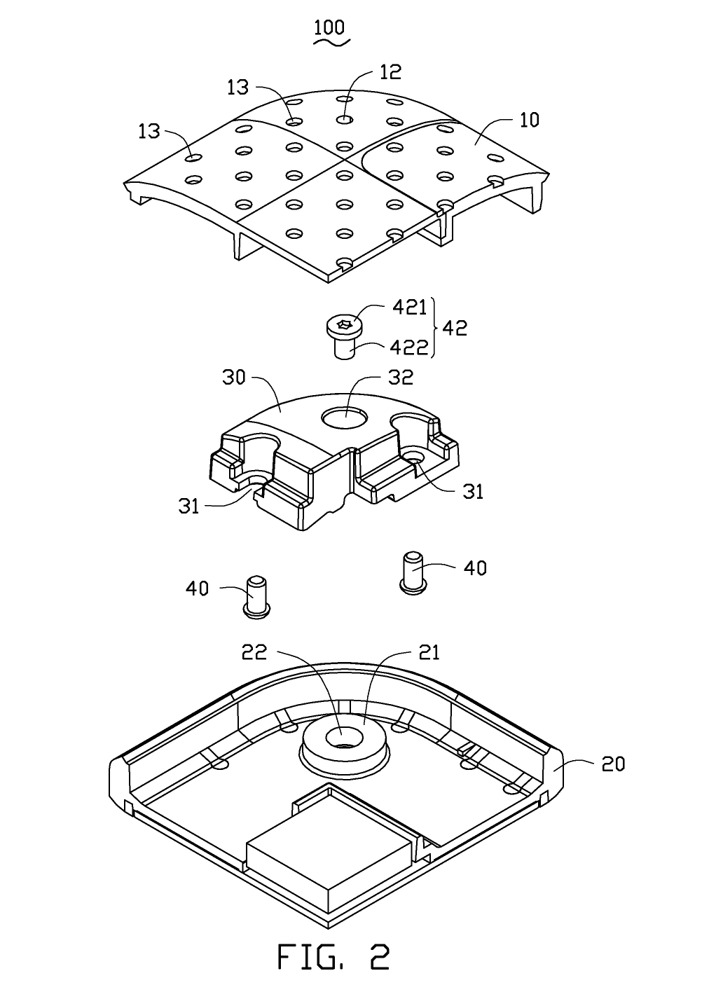

FIG. 1 is an exemplary embodiment of a disclosure of a hosing 100 of an electronic device. The housing 100 includes a back shell 10, a main body 20, and at least one connection element 30 for connecting the back shell 10 to the main body 20. In the embodiment, the back shell 10 is fixed to the main body 20 via four connection elements 30 located at the four corners of the electronic device. FIG. 2 shows one of the corners of the back shell 10 and a corresponding connection element 30. In alternative embodiments, the number of the connection element 30 can be varied according to need.

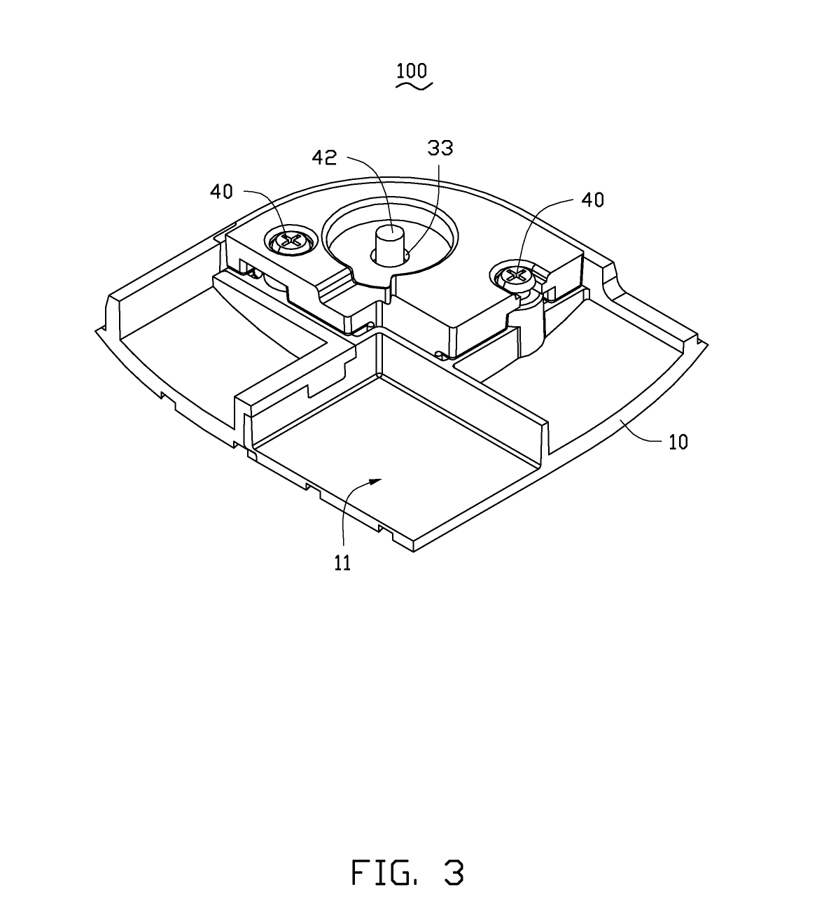

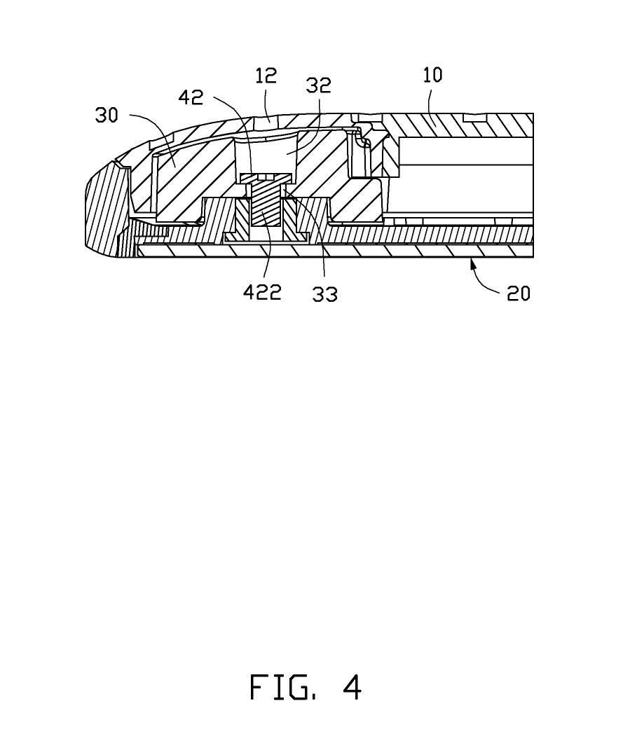

FIGS. 3 and 4 show that the connection element 30 is fixed to the inner surface 11 of the back shell 10 via first fixing elements 40. In the illustrated embodiment, the first fixing elements 40 are screws. The connection element 30 defines a connection hole 31. The first fixing element 40 penetrates through the connection hole 31 and is screwed into the thread hole (not shown) of the back shell 10, thus fixing the connection element 30 to the back shell 10. In an alternative embodiment, the connection element 30 may be fixed on the inner surface 11 via hooks or glue.

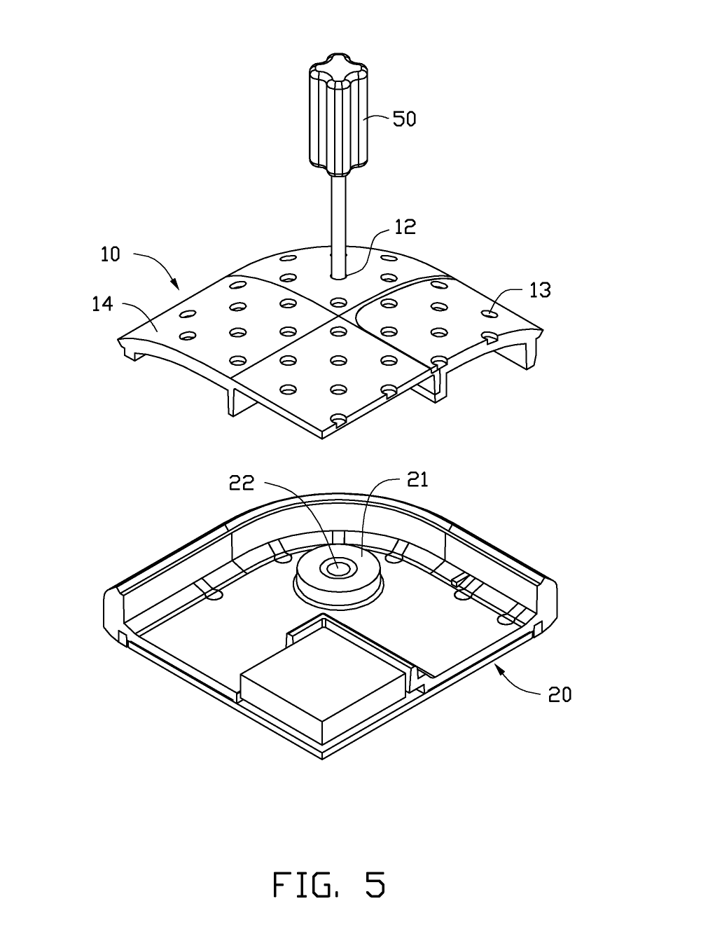

FIGS. 4 and 5 show that the connection element 30 defines a receiving hole 32 in a top surface and a through hole 33 in the bottom surface close to the main body 20. The receiving hole 32 is used for receiving a head 421 of a second fixing element 42. In the illustrated embodiment, the second fixing element 42 is a screw. A post 21 protrudes from the inner surface of the main body 20 and defines a threaded hole 22. The bolt 422 of the second fixing element 42 passes through the through hole 33 and is screwed into the threaded hole 22. Thus, the back shell 10 is fixed to the main body 20. In an alternative embodiment, the second fixing element 42 can be a screw bolt.

The back shell 10 defines at least one assembly hole 12 located corresponding to the receiving holes 32. The inner diameter of the assembly hole 12 is smaller than the inner diameter of the receiving hole 32 and the diameter of the head 421 of the second fixing element 42. The bolt 422 of the second fixing element 42 is screwed into the threaded hole 22 by the screwdriver 50 passing through the assembly hole 12, thus fixing the back shell 10 to the main body 20.

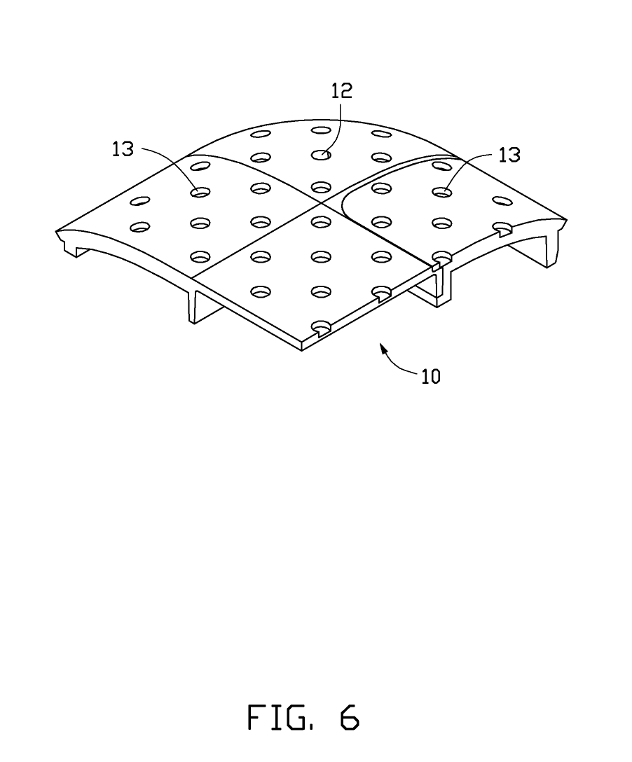

FIG. 6 shows that in the illustrated embodiment, a number of regularly arranged decoration holes 13 are defined on the back shell 10. The diameter of the decoration hole 13 is equal to that of the assembly hole 12. The decoration hole 13 can be selected from the group consisting of, a blind hole, a through hole, a golf hole, and a semicircular concave hole. The number of holes 13 surrounds the assembly hole 12.

In the embodiment, the diameter of the bolt 422 is 2 mm, and the diameter of the head 421 is about 3-4 mm. The diameter of the shank of the screwdriver 50 is about 1.4 mm. The inner diameter of the assembly hole 12 is about 1.4 mm.

In assembly, the second fixing element 42 is received in the receiving hole 32, and the first fixing element 40 passes through the connection hole 31 and is screwed into the inner surface 11 of the back shell 11. The connection element 30 is fixed to the back shell 11, then the shank of the screwdriver 50 passes through the assembly hole 12 to thread the second fixing element 42 into the threaded hole 22, thus fixing the back shell 10 to the main body 20.

With such a configuration, the screw 42 is hidden under the back shell 10 defining a smaller through hole 12 that the shank of the screwdriver 50 can pass through. Thus, the look of the electronic device 100 is more appealing and the assembly and disassembly of the electronic device 100 are easy.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. A housing comprising:
a back shell defining an assembly hole;
a main body;
a fixing element comprising a head; and
a connection element fixed to the back shell, the connection element defining a receiving hole for receiving the head of the fixing element and a through hole aligned with the assembly hole;
wherein an inner diameter of the assembly hole is smaller than an inner diameter of the receiving hole and the diameter of the head of the fixing element, and the assembly hole is sized to enable a shank of a screwdriver to extend therethrough and drive the fixing element to threadedly engage into the main body.

2. The housing as described in claim 1, wherein the back shell further defines a plurality of decoration holes, the plurality of decoration holes surrounds the assembly hole.

3. The housing as described in claim 2, wherein the plurality of decoration holes are selected from the group consisting of: blind holes, through holes, golf holes, and semicircular concave holes.

4. The housing as described in claim 1, wherein the fixing element is a screw.

5. The housing as described in claim 4, wherein a post protrudes from an inner surface of the main body, the post defines a threaded hole for engaging with the screw.

6. An electronic device comprising a housing, the housing comprising:
a back shell defining an assembly hole;
a main body;
a fixing element comprising a head; and
a connection element fixed to the back shell, the connection element defining a receiving hole for receiving the head of the fixing element and a through hole aligned with the assembly hole;
wherein an inner diameter of the assembly hole is smaller than an inner diameter of the receiving hole and the diameter of the head of the fixing element, and the assembly hole is sized to enable a shank of a screwdriver to extend therethrough and drive the fixing element to threadedly engage the main body.

7. The electronic device as described in claim 6, wherein the back shell further defines a plurality of decoration holes, the plurality of decoration holes surrounds the assembly hole.

8. The electronic device as described in claim 7, wherein the plurality of decoration holes are selected from the group consisting of: blind holes, through holes, golf holes, and semicircular concave holes.

9. The electronic device as described in claim 6, wherein the fixing element is a screw.

10. The electronic device as described in claim 9, wherein a post protrudes from an inner surface of the main body, the post defines a threaded hole for engaging with the screw.
